(19) United States
(12) Patent Application Publication
(10) Pub. No.: US 2018/0031670 A1
(43) Pub. Date: Feb. 1, 2018

(54) PRINTED CIRCUIT BOARD ON WHICH VIBRATION COMPONENT FOR GENERATING VIBRATION IS MOUNTED

(71) Applicant: CANON KABUSHIKI KAISHA, Tokyo (JP)

(72) Inventors: Michio Fukushima, Yokohama-shi (JP); Junnosuke Yokoyama, Toride-shi (JP); Manabu Hada, Kawasaki-shi (JP); Yusuke Horishita, Nagareyama-shi (JP)

(21) Appl. No.: 15/660,230

(22) Filed: Jul. 26, 2017

(30) Foreign Application Priority Data
Jul. 29, 2016 (JP) 2016-150105

(51) Int. Cl. G01S 3/80; G01H 11/08; H05K 1/02

(52) U.S. Cl. CPC G01S 3/80; H05K 1/0213; G01H 11/08

(57) ABSTRACT

There is provided a printed circuit board, on which a piezoelectric element for generating vibration is mounted, is fixed to a pedestal. Two slits are formed on a straight line that connects first position where the piezoelectric element is mounted on the printed circuit board and a second position where the printed circuit board is in contact with the pedestal.

### BACKGROUND

### Field

An aspect of the present invention generally relates to a shape of a printed circuit board on which a vibration component for generating vibration is mounted.

### Description of the Related Art

An information processing apparatus of recent years has been provided with a sensor for detecting a person who uses the information processing apparatus (hereinafter, referred to as “human detection sensor”). Japanese Patent Application Laid-Open No. 2015-195548 discusses an image forming apparatus provided with an ultrasonic sensor (i.e., vibration component) as a human detection sensor.

The ultrasonic sensor is mounted on a printed circuit board on which a driving circuit for outputting an ultrasonic wave and an amplification circuit for amplifying a reflected wave of the received ultrasonic wave are mounted. The ultrasonic sensor outputs the ultrasonic wave when a voltage is applied to a piezoelectric element to make the piezoelectric element vibrate. Further, the piezoelectric element is vibrated with a reflected wave of the output ultrasonic wave, so that the ultrasonic sensor outputs a detection result (e.g., voltage value) according to the vibration.

The vibration of the ultrasonic sensor propagates to the other members of the printed circuit board on which the ultrasonic wave is mounted. Then, the other members vibrate along with the vibration of the ultrasonic sensor, so that the vibration thereof propagates to the ultrasonic sensor via the printed circuit board. In this way, the vibration of the other members induced by the vibration of the ultrasonic sensor propagates to the ultrasonic sensor via the printed circuit board.

### SUMMARY

An aspect of the present invention is directed to a printed circuit board capable of suppressing vibration of other members induced by a vibration component mounted on a printed circuit board from propagating to the vibration component via the printed circuit board.

According to an aspect of the present invention, a printed circuit board is fixed to a pedestal, and a vibration component that generates vibration in the operation period is mounted thereon. A slit is formed on the printed circuit board, and this slit is formed on a straight line that connects a first position where the vibration component is mounted on the printed circuit board and a second position where the printed circuit board is in contact with the pedestal.

Further features of aspects of the present invention will become apparent from the following description of exemplary embodiments with reference to the attached drawings.

### BRIEF DESCRIPTION OF THE DRAWINGS

FIG. 1 is a block diagram of a multifunction peripheral (MFP).

FIG. 2 is a block diagram illustrating details of the MET.

FIG. 3 is a diagram illustrating a detection area of an ultrasonic sensor.

FIG. 4 is a diagram illustrating a perspective view of a human detection sensor unit.

FIG. 5 is a block diagram illustrating devices mounted on a board.

FIG. 6 is a diagram illustrating a human detection sensor unit before and after a horn is attached thereto.

FIGS. 7A, 7B, and 7C are diagrams respectively illustrating a front view, a top view, and a cross-sectional view of the human detection sensor unit.

FIG. 8 is a diagram illustrating a plan view of a board on which an ultrasonic sensor is mounted.

FIGS. 9A, 9B, 9C, and 9D are diagrams illustrating a detailed structure of the horn.

FIGS. 10A and 10B are diagrams illustrating a shock-absorbing member attached to the horn.

FIGS. 11A and 11B are diagrams illustrating cross-sectional views of the human detection sensor unit.

FIG. 12 is a diagram illustrating a state where a user approaches the MFP from a front face thereof.

FIG. 13 is a diagram illustrating a state where a user approaches the MFP from a side face thereof.

FIG. 14 is a diagram illustrating a state where a person passes in front of the MFP.

FIG. 15 is a flowchart illustrating return algorithm based on a detection result of the ultrasonic sensor.

FIGS. 16A, 16B, and 16C are diagrams illustrating variation examples of the board.

### DESCRIPTION OF THE EMBODIMENTS

Hereinafter, an exemplary embodiment of the present invention will be described with reference to the appended drawings. An exemplary embodiment in which the present invention is applied to a multifunction peripheral (MFP) having a plurality of functions such as scanning, printing, and copying will be described.

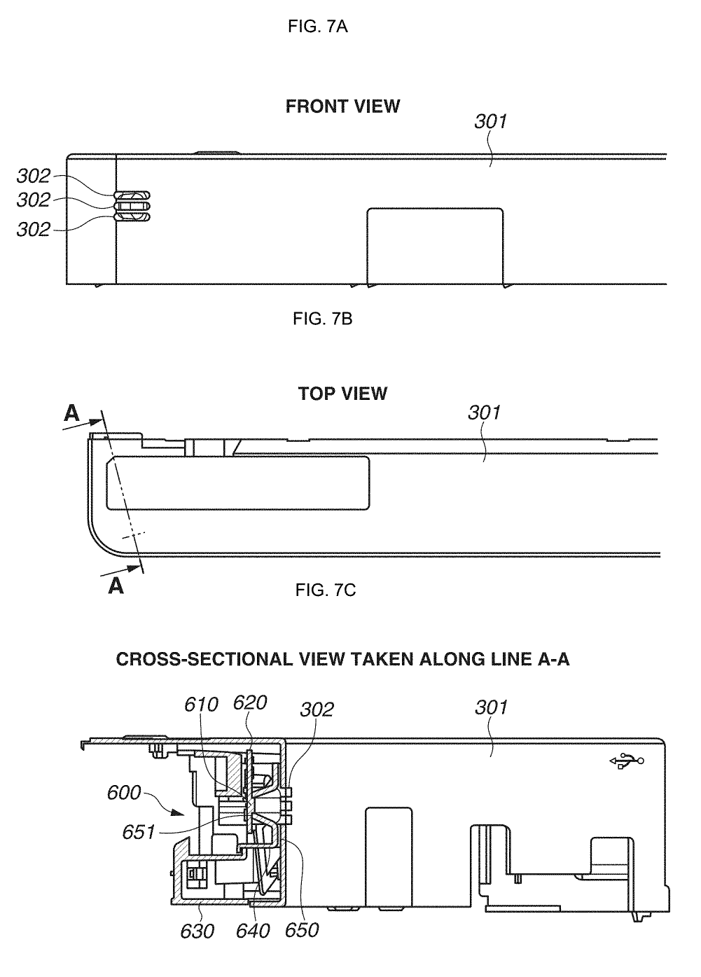

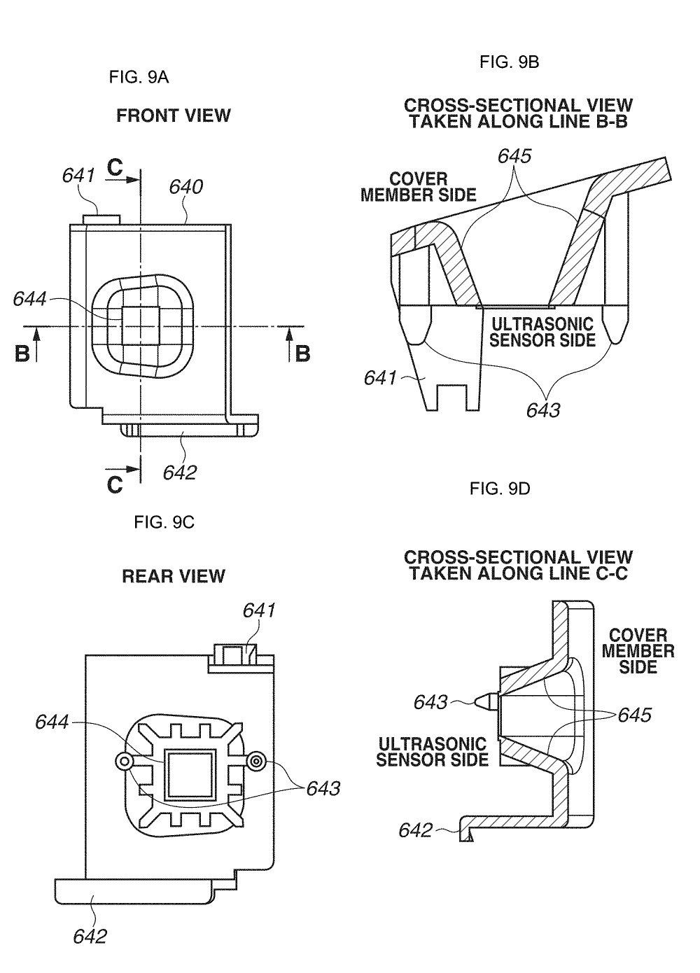

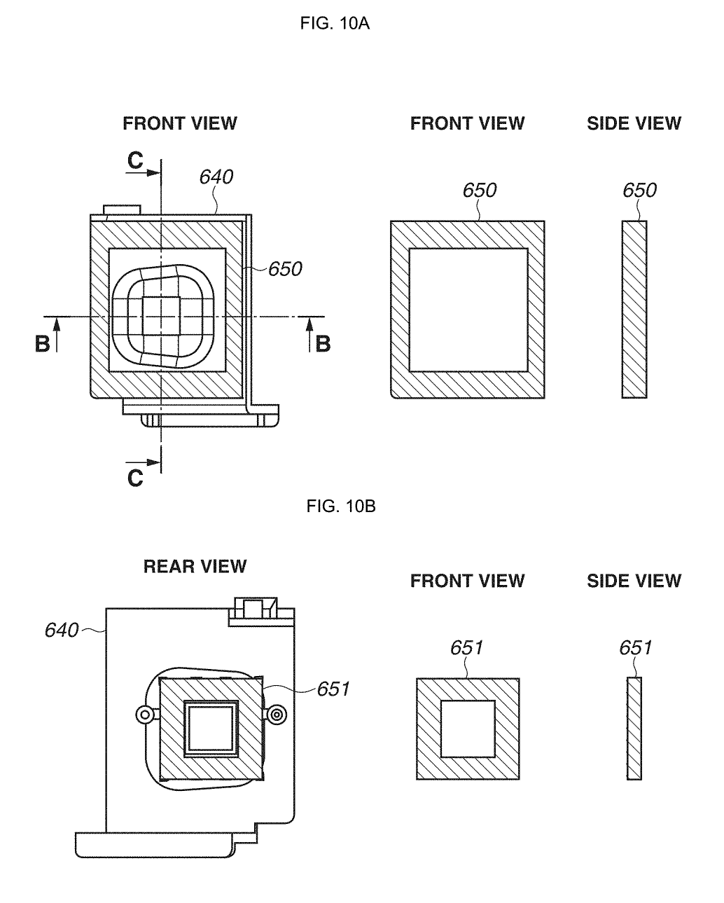

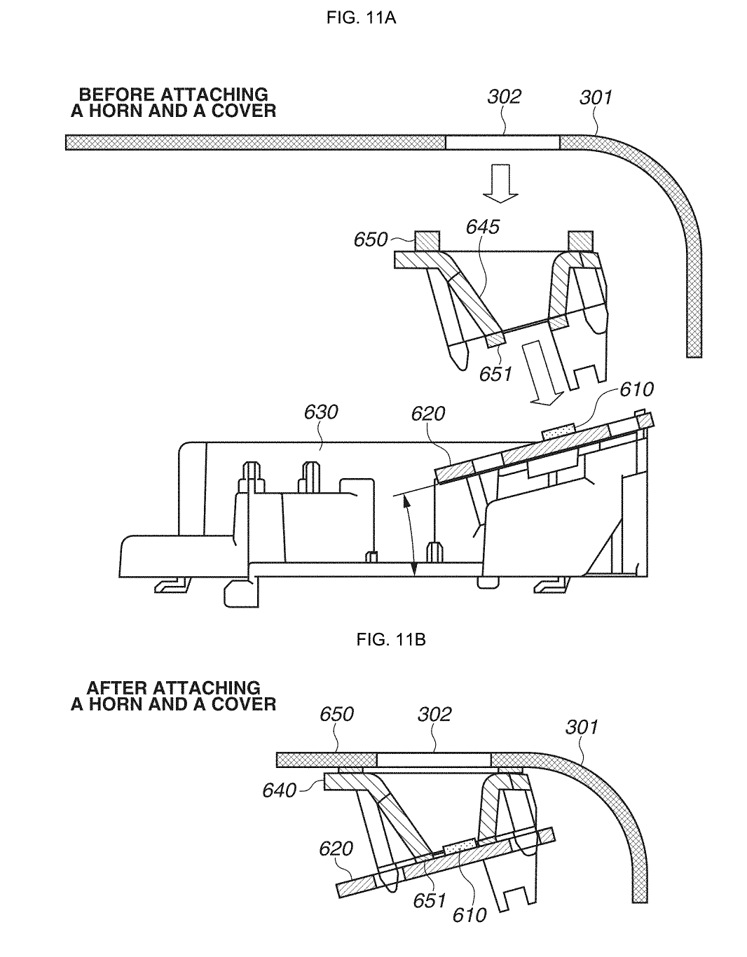

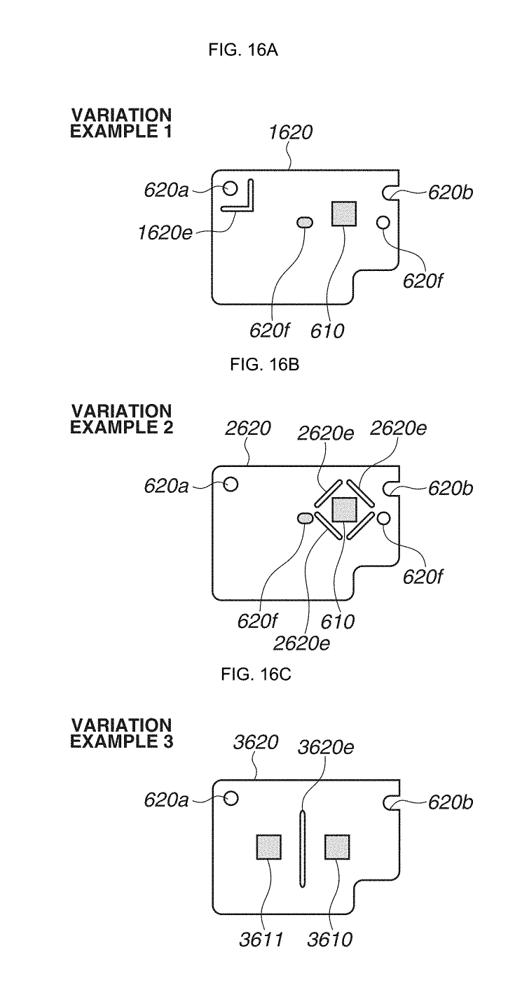

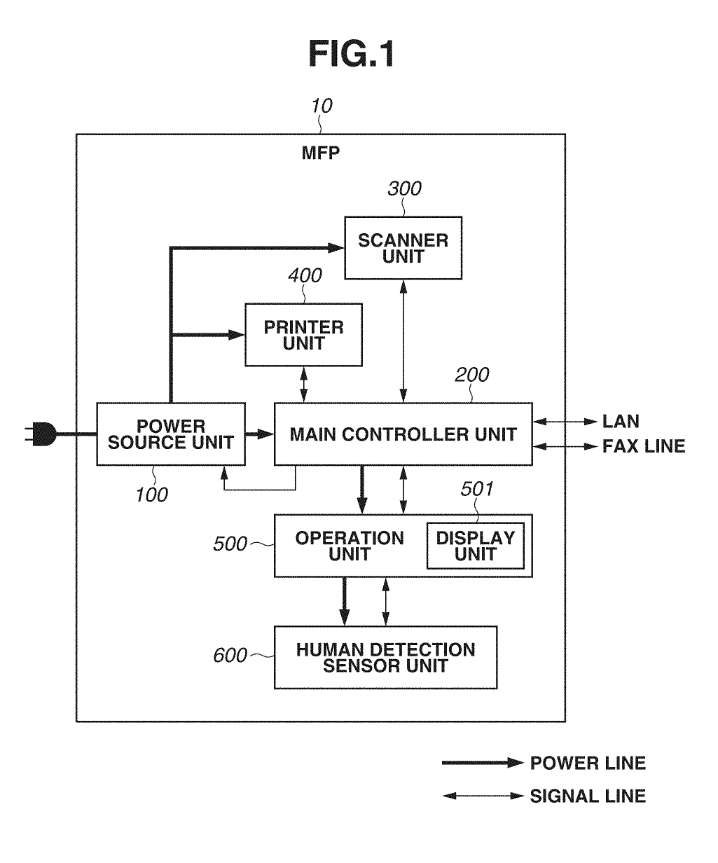

FIG. 1 is a block diagram schematically illustrating an MFP.

An MFP 10 includes a power source unit 100, a main controller unit 200, a scanner unit (reading unit) 300, a printer unit (printing unit) 400, an operation unit 500, and a human detection sensor unit 600. The MFP 10 includes at least two power modes. The MFP 10 includes a stand-by mode in which functions such as scanning, printing, and copying can be executed, and a sleep mode in which power consumption is lower than that of the stand-by mode. The stand-by mode and the sleep mode respectively corresponds to a state S0 and a state S3 specified in the Advanced Configuration and Power Interface (ACPI) standard.

The MFP 10 shifts to a sleep mode from a stand-by mode when a condition of shifting to the sleep mode is satisfied. More specifically, the MFP 10 shifts to a sleep mode from a stand-by mode when a predetermined time has passed without the user operating the operation unit 500 in the stand-by mode. The condition of shifting to the sleep mode is not limited to the above-described passage of a predetermined time, and the MFP 10 also shifts to the sleep mode when a user operates a power saving button provided on the operation unit 500, when the time has reached a preset sleep mode shifting time, or when a predetermined time has passed without executing printing processing or scanning processing.

In the sleep mode, power supplied to the main controller unit 200, the scanner unit 300, the printer unit 400, and the operation unit 500 is limited. Further, in the sleep mode, display unit 501 of the operation unit 500 is turned off. In the stand-by mode, the display unit 501 of the operation unit 500 is turned on. In the stand-by mode, power is supplied to the main controller unit 200, the scanner unit 300, the printer unit 400, and the operation unit 500.

in the sleep mode, power is supplied to the human detection sensor unit 600. The human detection sensor unit 600 does not operate in the stand-by mode whereas the human detection sensor unit 600 operates in the sleep mode. In the sleep mode, the MFP 10 shifts to the stand-by mode from the sleep mode based on a detection result of the human detection sensor unit 600.

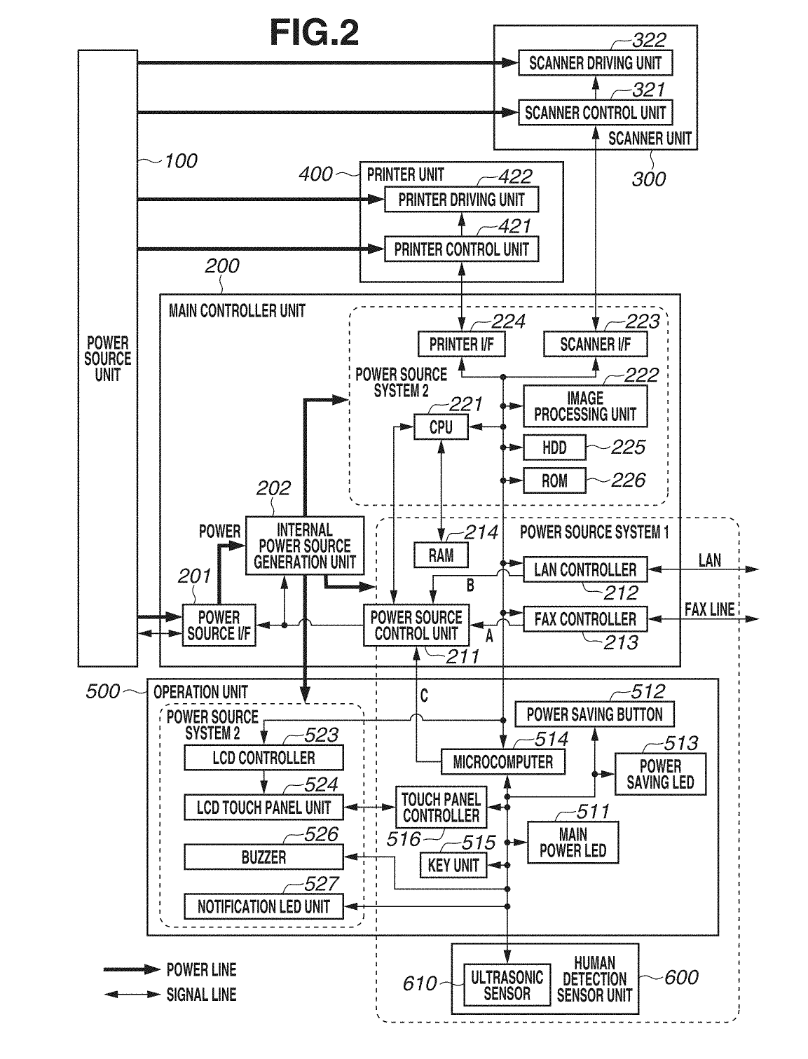

FIG. 2 is a block diagram illustrating details of the MFP 10.

The scanner unit 300 optically reads an image of a document and generates image data. The scanner unit 300 includes a scanner control unit 321 and a scanner driving unit 322. The scanner driving unit 322 includes a driving unit for moving a reading head for reading an image of a document and a driving unit for conveying a document to a reading position. The scanner control unit 321 controls the operation of the scanner driving unit 322. When scanning processing is executed, the scanner control unit 321 communicates with the main controller unit 200 to receive setting information set by the user and controls the operation of the scanner driving unit 322 based on the received setting information.

The printer unit 400 forms an image on a recording medium (sheet) through an electrophotographic method. The printer unit 400 includes a printer control unit 421 and a printer driving unit 422. The printer driving unit 422 includes (and not shown) a motor rotating a photosensitive drum, a mechanism portion for pressurizing a fixing unit, and a heater. The printer control unit 421 controls the operation of the printer driving unit 422. When printing processing is executed, the printer control unit 421 communicates with the main controller unit 200 to receive setting information set by the user and controls the operation of the printer driving unit 422 based on the received setting information.

The main controller unit 200 controls the operations of the scanner unit 300 and the printer unit 400. For example, the main controller unit 200 controls the scanner unit 300 to read an image of a document and generate image data according to a copying instruction input to the operation unit 500. Then, the main controller unit 200 executes image processing on the generated image data and outputs the processed image data to the printer unit 400. Then, the main controller unit 200 controls the printer unit 400 to print an image.

The main controller unit 200 includes at least two power source systems, i.e., power source system 1 which includes devices that have to operate in the sleep mode and a power source system 2 which includes devices that do not have to operate in the sleep mode. An internal power source generation unit 202 receives power from the power source unit 100 via a power source interface (I/F) 201 and supplies power to the devices in the power source system 1 in the sleep mode. In the sleep mode, power is not supplied to the devices in the power source system 2.

in addition, power supply with respect to the devices in the power source system 2 does not have to be stopped but may be limited in the sleep mode. Further, clock-gating may be performed with respect to the devices in the power source system 2 or clock frequency may be lowered in the sleep mode. The devices in the power source system 1 include a power source control unit 211, a local area network (LAN) controller 212, a facsimile (FAX) controller 213, and a random access memory (RAM) 214. In order to enable the MFP 10 to return to the stand-by mode when the MFP 10 receives a fax or receives a print request through the network during the sleep mode, power is supplied to the fax controller 213 or the LAN controller 212 in the sleep mode.

In the stand-by mode, the internal power source generation unit 202 supplies power to the devices in the power source system 2. The devices in the power source system 2 include a central processing unit (CPU) 221, an image processing unit 222, a scanner I/F 223, a printer I/F 224, a hard disk drive (HDD) 225, and a read only memory (ROM) 226. In the sleep mode, power supply to the devices in the power source system 2 is stopped.

The power source control unit 211 is a device for controlling a power mode of the MFP 10. The power source control unit 211 may be configured of a processor that executes software, or may be configured of a logic circuit. Interrupt signal A, B, or C is input to the above-described power source control unit 211. When the interrupt signal A, B, or C is input to the power source control unit 211 in the sleep mode, the power source control unit 211 controls the internal power source generation unit 202 to supply power to the devices in the power source system 2. Through this operation, the MFP 10 returns to the stand-by mode from the sleep mode.

The interrupt signal A is a signal output from the fax controller 213, and the fax controller 213 outputs the interrupt signal A when a fax is transmitted through a fax line. The interrupt signal B is a signal output from the LAN controller 212, and the LAN controller 212 outputs the interrupt signal B when a print job packet or a status check packet is received through a LAN. The interrupt signal C is a signal output from a microcomputer 514 of the operation unit 500, and the microcomputer 514 outputs the interrupt signal C when existence of a user of the MFP 10 is determined based on a detection result of the human detection sensor unit 600 or when a power saving button 512 is pressed.

Because the interrupt signal A, B, or C is input thereto, the CPU 221 receives power and makes the MFP 10 return to a state before shifting to the sleep mode. More specifically, the CPU 211 reads out information indicating a state of the MFP 10 from the RAM 214 that has been executing self-refresh operation in the sleep mode. Then, the CPU 211 uses the read information to bring back the MFP 10 to a state before shifting to the sleep mode. Then, the CPU 221 executes processing according to the return factor of the interrupt signal A, B, or C.

The operation unit 500 includes a liquid crystal display (LCD) touch panel unit 524 (display unit 501) integrally configured of an LCD panel and a touch panel, a key unit 515 for detecting key operations of a numerical keypad or a start key performed by the user, and a buzzer 526. An image corresponding to the image data generated by the CPU 221 of the main controller unit 200 is rendered on the LCD touch panel unit 524. An LCD controller 523 receives image data from the CPU 221 and displays an image on the LCD touch panel unit 524 based on the image data. When the user touches a screen of the LCD touch panel unit 524, a touch panel controller 516 analyzes coordinate data of touched position and notifies the coordinate data to the microcomputer 514. The microcomputer 514 notifies the coordinate data to the CPU 221. In addition, the microcomputer 514 may notify the CPU 221 of information indicating a touched icon instead of the coordinate data. The microcomputer 514 periodically scans operations performed on the key unit 515. Then, if the microcomputer 514 determines that the key unit 515 is operated by the user, the microcomputer 514 notifies the CPU 221 of information about the operated key unit 515. The CPU 221 is notified of the user operation with respect to the LCD touch panel 524 or the key unit 515 to make the MFP 10 operate according to the user operation.

The operation unit 500 includes a plurality of light-emitting diodes (LEDs). A main power LED 511 is turned on when a main power of the MFP 10 is ON. A notification LED unit 527 is turned on through the control of the microcomputer 514, and notifies the user of a state of the MFP 10 when a job is executed or an error has occurred.

Similar to the main controller unit 200, the operation unit 500 also includes at least two power source systems, i.e., a power source system 1 which includes devices that have to operate in the sleep mode and a power source system 2 which includes devices that do not have to operate in the sleep mode. The devices in the power source system 1 includes the microcomputer 514, the main power LED 511, the power saving button 512, the power saving LED 513, the touch panel controller 516, and the key unit 515. The devices in the power source system 2 includes the LCD controller 523, the LCD touch panel unit 524, the buzzer 526, and the notification LED unit 527. In order to enable the MFP 10 to return to the stand-by mode from the sleep mode when the user operates the power saving button 512 in the sleep mode, power is supplied to the power saving button 512 and the power saving LED 513 for lighting up the power saving button 512 in the sleep mode.

The human detection sensor unit 600 is a device included in the power source system 1, and operates in the sleep mode to detect a user of the MFP 10. The human detection sensor unit 600 includes an ultrasonic sensor 610. The microcomputer 514 periodically reads and analyzes a detection result of the ultrasonic sensor 610 to determine whether the user of the MFP 10 exists. The ultrasonic sensor 610 according to the present exemplary embodiment is a sensor that executes output and reception of the ultrasonic waves through a single chip. In addition, the ultrasonic sensor 610 may be configured of an oscillation chip for outputting the ultrasonic wave and a reception chip for receiving the ultrasonic wave. The ultrasonic sensor (vibration component) 610 of the present exemplary embodiment makes a piezoelectric element arranged inside the ultrasonic sensor 610 vibrate to output the ultrasonic wave, and outputs an electric signal (voltage value) corresponding to the vibration received by the piezoelectric element.

In the present exemplary embodiment, although an exemplary embodiment using the ultrasonic sensor 610 will be described, a sensor other than the ultrasonic sensor 610 may be used. For example, a pyroelectric sensor or an infrared sensor may be used instead of the ultrasonic sensor 610.

The microcomputer 514 outputs an oscillation signal to the ultrasonic sensor 610 for a certain period. With this operation, the piezoelectric element of the ultrasonic sensor 610 is vibrated, and an ultrasonic wave in a non-audible range of 40 KHz is output for a certain period. Thereafter, the microcomputer 514 determines existence of the user of the MFP 10 based on a detection result of the ultrasonic wave received by the ultrasonic sensor 610. The microcomputer 514 outputs an interrupt signal C to the power source control unit 211 when existence of the user of the MFP 10 is determined. When the interrupt signal C is input thereto, the power source control unit 211 controls the power source unit 100 to return the power mode of the MFP 10 to the stand-by mode from the sleep mode. Further, in the present exemplary embodiment, although an exemplary embodiment in which power is supplied to the human detection sensor unit 600 from the internal power source generation unit 202 has been described, power may be directly supplied to the human detection sensor unit 600 from the power source unit 100.

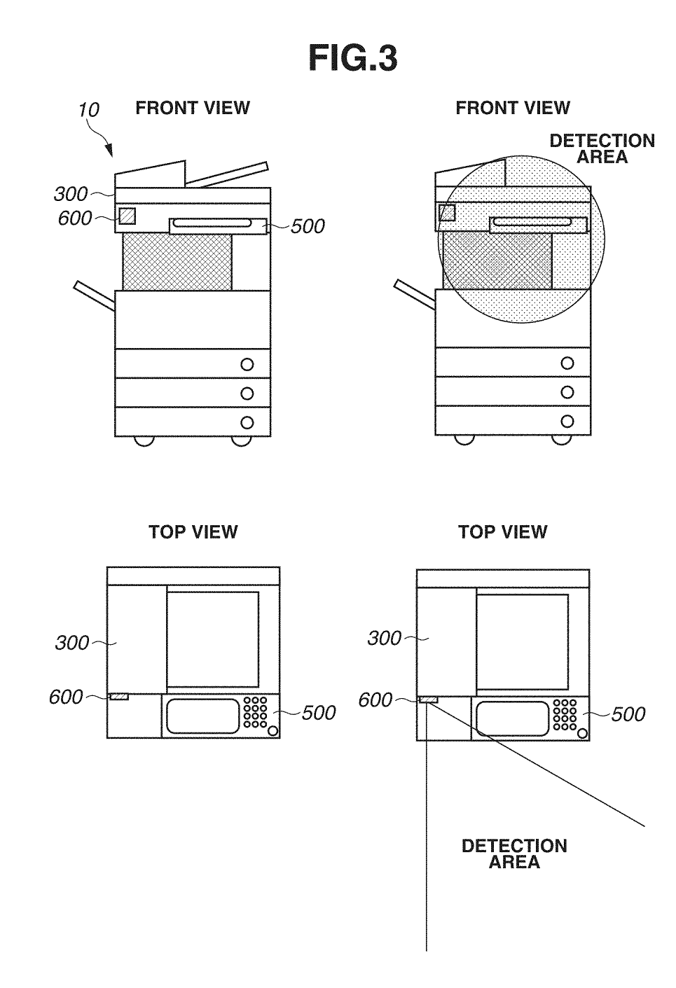

FIG. 3 is a diagram illustrating a detection area of the ultrasonic sensor 610.

The ultrasonic sensor 610 according to the present exemplary embodiment outputs an ultrasonic wave and receives an ultrasonic wave reflected on an object such as a human (hereinafter, referred to as “reflected wave” as appropriate). A distance to the object or the human can be estimated based on the time taken to receive the reflected wave after outputting the ultrasonic wave. In the present exemplary embodiment, the microcomputer 514 calculates a distance to the human or the object based on a detection result of the ultrasonic sensor 610.

The ultrasonic sensor 610 is disposed so as to make a front side or a slightly lower side of the MFP 10 be set as a detection area of the ultrasonic sensor 610. The detection area is a range within 2 m from the MFP 10. The human detection sensor unit 600 is disposed at a position on a front side of the scanner unit 300 and an opposite side of the operation unit 500 when the MFP 10 is viewed from the front. The human detection sensor unit 600 is disposed so as to be inclined toward the operation unit 500, so that a user standing in front of the operation unit 500 can be detected thereby.

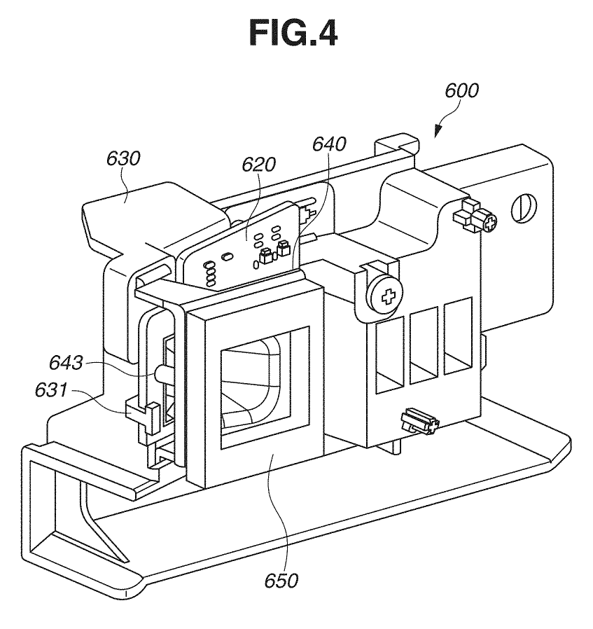

FIG. 4 is a perspective view of the human detection sensor unit 600.

The human detection sensor unit 600 includes a printed circuit board 620 on which the ultrasonic sensor 610 is mounted, a pedestal 630 to which the printed circuit board 620 is fixed, a horn 640 for controlling directionality of the ultrasonic wave output from the ultrasonic sensor 610, and a shock-absorbing member (sponge) 650. Hereinafter, the printed circuit board 620 is also referred to as “board 620” appropriate. The ultrasonic sensor 610 is surface mount device (SMD) type ultrasonic sensor mounted on a surface of the board 620. The ultrasonic sensor 610 includes a piezoelectric element which outputs an ultrasonic wave according to an applied voltage and outputs an electric signal corresponding to a received ultrasonic wave.

The pedestal 630 is a member used for arranging the board 620 on which the ultrasonic sensor 610 is mounted to be inclined toward the operation unit 500.

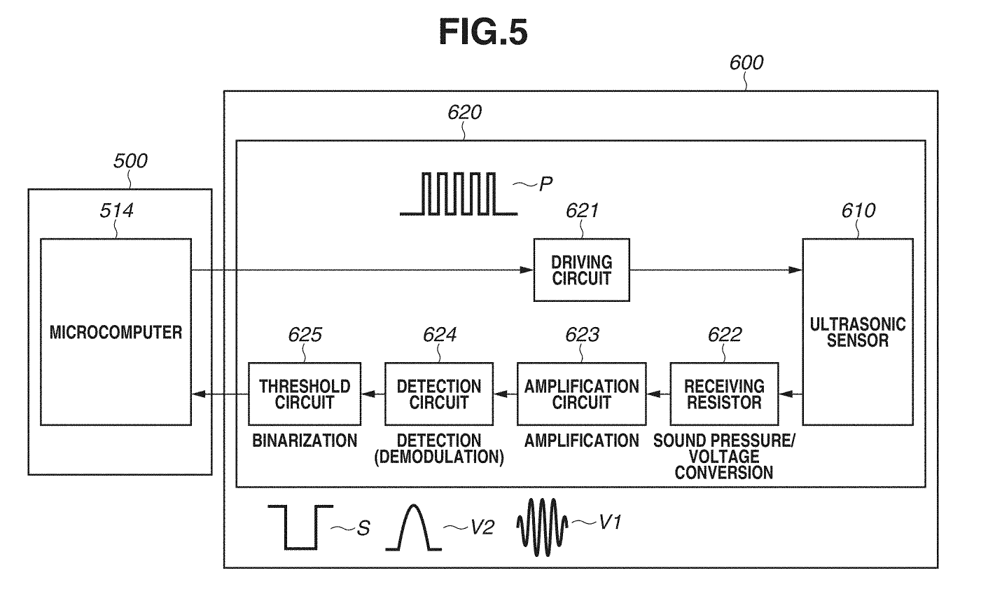

FIG. 5 is a block diagram illustrating devices mounted on the board 620.

The board 620 is a two-layered glass epoxy board. As illustrated in FIG. 5, the ultrasonic sensor 610, a driving circuit 621, a receiving resistor 622, an amplification circuit 623, a detection circuit 624, and a threshold circuit 625 are mounted on the board 620. The driving circuit 621 receives a driving pulse P output from the CPU 221 to vibrate the piezoelectric element of the ultrasonic sensor 610. The receiving resistor 622 converts sound pressure of the ultrasonic wave received by the ultrasonic sensor 610 to voltage. The amplification circuit 623 amplifies the converted voltage. A voltage wave form V1 amplified by the amplification circuit 623 is demodulated by the detection circuit 624. Then, a signal V2 output from the detection circuit 624 is compared to a voltage level set to the threshold circuit 625. Then, the signal is output as an analog signal S from the threshold circuit 625 to the microcomputer 514. The board 620 on which the ultrasonic sensor 610 is mounted is arranged so as to be inclined toward the operation unit 500 by approximately 15 degrees from a front face of the MFP 10. In addition, the angle of the board 620 is not limited to the above-described 15 degrees, and may be adjusted based on a positional relationship between the operation unit 500 and the human detection sensor unit 600. More specifically, the angle is smaller when a distance between the operation unit 500 and the human detection sensor unit 600 is shorter, and the angle is larger when a distance therebetween is longer.

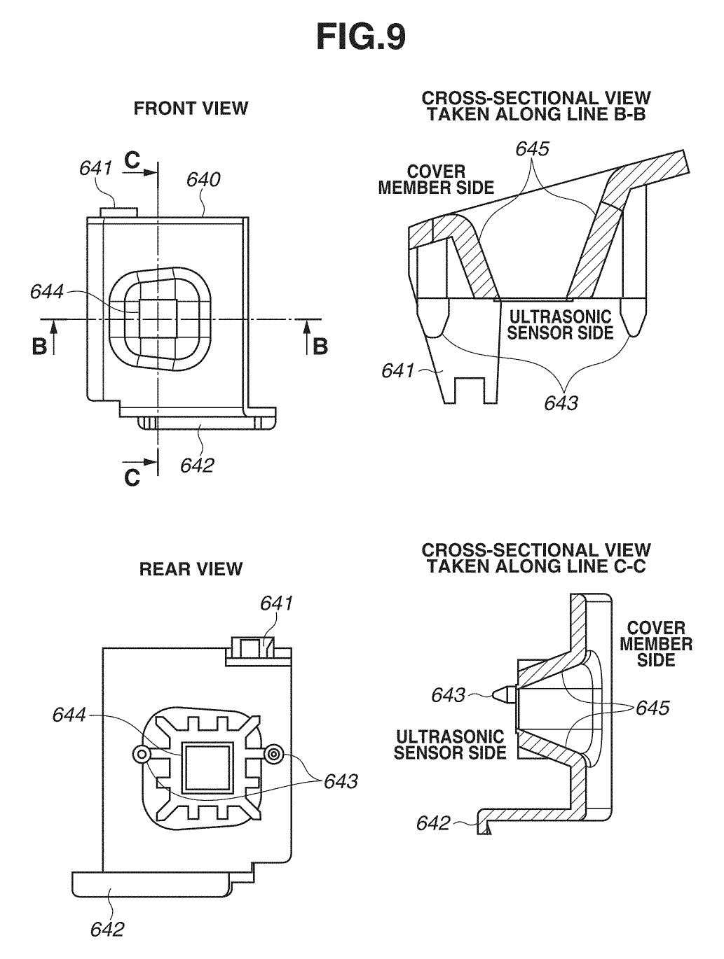

The horn 640 is a member for controlling directionality of the ultrasonic wave to prevent diffusion of the ultrasonic wave output from the ultrasonic sensor 610. It is difficult to limit the detection area without using the horn 640. An opening portion 644 of the horn 640 on a side of the cover member 301 (see FIG. 9) has a square shape with a size of approximately 13 mm×13 mm, and the size of the opening portion 644 is gradually narrowed down toward the ultrasonic sensor 610 (i.e., inverted conical shape). In addition, an opening size of the opening portion 644 of the horn 640 is not limited to the above-described size.

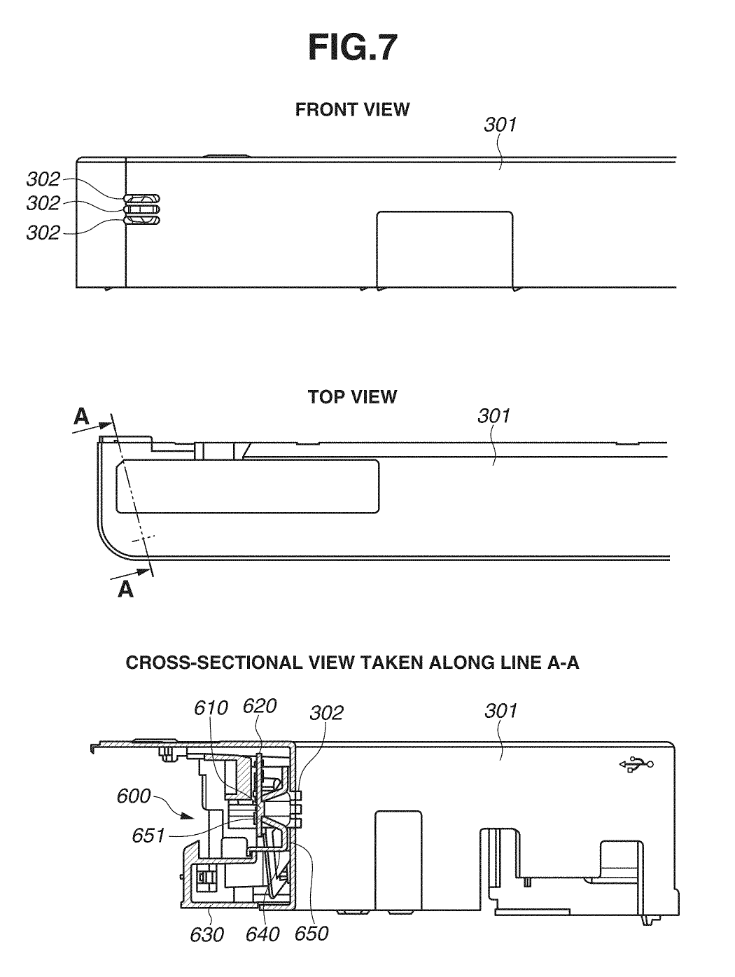

The shock-absorbing member 650 is arranged between the horn 640 and a cover member 301 (see FIG. 7C) described below. The shock-absorbing member 650 fills a space between the horn 640 and the cover member 301, so that the ultrasonic wave does not leak through the space between the horn 640 and the cover member 301.

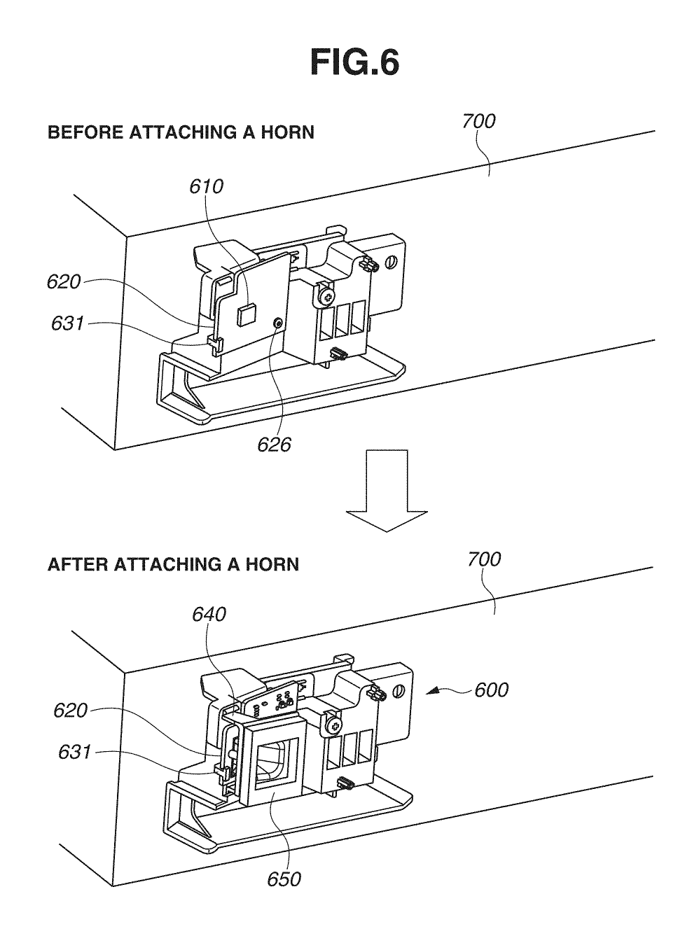

FIG. 6 is a diagram illustrating the human detection sensor unit 600 before and after the horn 640 is attached thereto.

The human detection sensor unit 600 is fixed to a frame plate (fixing member) 700 provided in the scanner unit 300. The board 620 is fixed to the pedestal 630 with a screw 626.

The horn 640 is arranged on a side of the board 620 where the ultrasonic sensor 610 is mounted. The horn 640 is fixed to the pedestal 630. The shock-absorbing member 650 is attached to an end portion of the horn 640 on a side of the cover member 301. The shock-absorbing member 650 is arranged between the horn 640 and the cover member 301, so as to fill the space between the horn 640 and the cover member 301. With this configuration, the ultrasonic wave output from the ultrasonic sensor 610 can be suppressed from leaking through the space between the horn 640 and the cover member 301. Further, because the shock-absorbing member 650 is made of sponge, vibration of the horn 640 can be suppressed from propagating to the cover member 301.

FIGS. 7A, 7B, and 70 are diagrams respectively illustrating a front view, a top view, and a cross-sectional view of the human detection sensor unit 600. FIG. 7A is a front view of a portion of the scanner unit 300 where the human detection sensor unit 600 is arranged, FIG. 7B is a top view of the portion of the scanner unit 300 where the human detection sensor unit 600 is arranged, and FIG. 70 is a cross-sectional view taken along a line A-A in FIG. 7B.

if the human detection sensor unit 600 is arranged at a position touchable by the user, the user's finger may touch the ultrasonic sensor 610 or the board 620 to cause malfunction of the ultrasonic sensor 610 or the board 620. Therefore, as illustrated in FIG. 7A, the human detection sensor unit 600 is covered by the cover member 301 of the scanner unit 300. The cover member 301 is provided with a plurality of slits 302 for outputting the ultrasonic wave output from the ultrasonic sensor 610 to the outside of the apparatus or receiving a reflected wave of the ultrasonic wave reflected from the outside thereof. Each of the slits 302 has an elongated hole shape extending in horizontal direction in the present exemplary embodiment, the three slits 302 are aligned in a vertical direction. Each of the slits 302 has a length (i.e., breadth) in the horizontal direction greater than the opening size of the horn 640 in the horizontal direction.

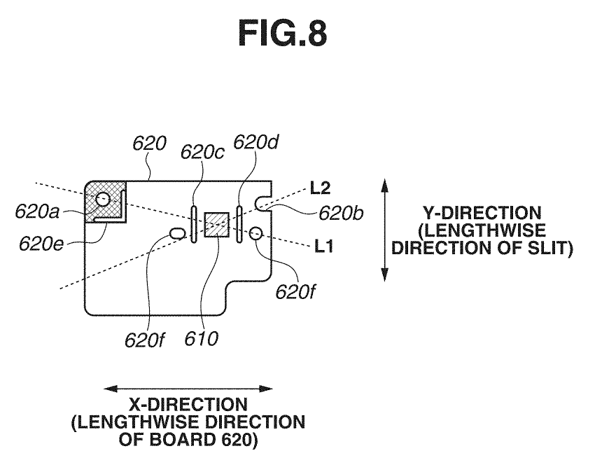

FIG. 8 is a diagram illustrating a plan view of the board 620 on which the ultrasonic sensor 610 is mounted.

The ultrasonic sensor 610 is mounted on the board 620. The above-described driving circuit 621, the receiving resistor 622, the amplification circuit 623, the detection circuit 624, and the threshold circuit 625 are mounted on the board 620 (they are not illustrated in FIG. 8). A screw hole (through-hole) 620a through which a screw 626 for fixing the board 620 to the pedestal 630 passes is formed on the board 620. In other words, a portion of the board 620 where the screw hole 620a is formed is a contact position (first position) of the pedestal 630 and the board 620. The screw 626 is fixed to the pedestal 630 via the screw hole 620a. Further, a cutout portion 620b for latching a claw portion 631 formed on the pedestal 630 is formed on an opposite end portion of the screw hole 620a of the board 620.

Furthermore, slits 620c and 620d are formed on both sides of the ultrasonic sensor 610 mounted on the board 620. The slit 620c is formed at a position between the ultrasonic sensor 610 and the screw hole 620a on the board 620. The slit 620c is formed on a straight line Li that connects a position (a hatched region in FIG. 8) where the ultrasonic sensor 610 is mounted on the board 620 and a position (a shading region in FIG. 8) where the board 620 is in contact with the pedestal 630. Further, the slit 620d is formed at a position between the ultrasonic sensor 610 and the cutout portion 620b on the board 620. The slit 620d is formed on a straight line L2 that connects a position where the ultrasonic sensor 610 is mounted on the board 620 and a position (i.e., cutout portion 20b) where the board 620 is in contact with the pedestal 630.

The slit 620c has a length in the lengthwise direction (Y-direction in FIG. 8) longer than a length of the ultrasonic sensor 610 in the Y-direction. Further, the slit 620d has a length in the lengthwise direction (Y-direction in FIG. 8) longer than the length of the ultrasonic sensor 610 in the Y-direction. The lengthwise direction (Y-direction) of the slit 620c is a direction orthogonal to a lengthwise direction (X-direction in FIG. 8) of the board 620. Further, the lengthwise direction (Y-direction) of the slit 620d is a direction orthogonal to the lengthwise direction (X-direction in FIG. 8) of the board 620.

Furthermore, an L-shaped slit 620e is formed at a position between the ultrasonic sensor 610 and the screw hole 620a on the board 620. The slit 620e is formed so as to surround the screw hole 620a Similar to the slit 620c, the slit 620e is also formed at a position between the ultrasonic sensor 610 and the screw hole 620a on the board 620. The slit 620e is formed on the straight line L1.

The slit 620c is formed on a side (one side) close to the ultrasonic sensor 610 from a central position between the hatched region and the shaded region in FIG. 8, whereas the slit 620e is formed on a side (another side) close to the screw hole 620a from the central position.

Because the slits 620c, 620d, and 620e are formed on the board 620, vibration of the ultrasonic sensor 610 can be prevented from propagating to the other members (i.e., the frame plate 700 and the pedestal 630) through the screw 626 and the claw portion 631. In addition, a metallic screw 626 is used when the board 620 and the frame plate 700 have to be connected electrically. However, when the board 620 and the frame plane 700 do not have to be connected electrically, a plastic screw 626 may be used. If the plastic screw 626 is used, vibration of the ultrasonic sensor 610 can be prevented from propagating to the other members through the screw 626.

Further, a boss hole 620f through which a boss 643 provided on the horn 640 passes is formed on the board 620 according to the present exemplary embodiment. The boss 643 provided on the horn 640 fits into the boss hole 620f, so that a relative position of the horn 640 with respect to the ultrasonic sensor 610 can be fixed with high precision. A shock-absorbing member 651 contacts a region indicated by hatched lines in FIG. 8. The shock-absorbing member 651 contacts a region where the slits 620c and 620d of the board 620 are formed.

FIGS. 9A, 9B, 90, and 9D are diagrams illustrating a detailed structure of the horn 640. FIG. 9A is a front view of the horn 640, FIG. 9B is a cross-sectional view taken along a line B-B in FIG. 9A, FIG. 9C is a rear view of the horn 640, and FIG. 9D is a cross-sectional view taken along a line C-C in FIG. 9A.

The horn 640 is a member for controlling directionality of the ultrasonic wave transmitted from the ultrasonic sensor 610 mounted on the board 620. As illustrated in FIGS. 9B and 9D, the horn 640 is formed into an inverted conical shape, so that an opening size thereof is gradually narrowed down toward the ultrasonic sensor 610. In the present exemplary embodiment, although an inner face 645 of the horn 640 consists of a plurality of planar faces, the inner face 645 may be formed of a curved face. The horn 640 is provided with latching portions 641 and 642 for fixing the horn 640 to the pedestal 630. The horn 640 is fixed to the pedestal 630 without being fixed to the board 620. By fixing the horn 640 to the pedestal 630, vibration of the ultrasonic sensor 610 is suppressed from propagating to the horn 640. In addition, the horn 640 may be fixed to the board 620 as long as vibration of the horn 640 can be sufficiently suppressed by the slits 620c, 620d, and 620e provided on the board 620.

Further, as illustrated in FIGS. 9B and 9C, two bosses 643 for fixing the position of the horn 640 with respect to the ultrasonic sensor 610 are formed on the horn 640. In order to output the ultrasonic wave from the ultrasonic sensor 610 with directionality, it is preferable that the horn 640 is arranged adjacent to the ultrasonic sensor 610. However, if the horn 640 is fixed to the board 620 on which the ultrasonic sensor 610 is mounted, vibration of the ultrasonic sensor 610 propagates to the horn 640. Further, the horn 640 disturbs the vibration of the ultrasonic sensor 610.

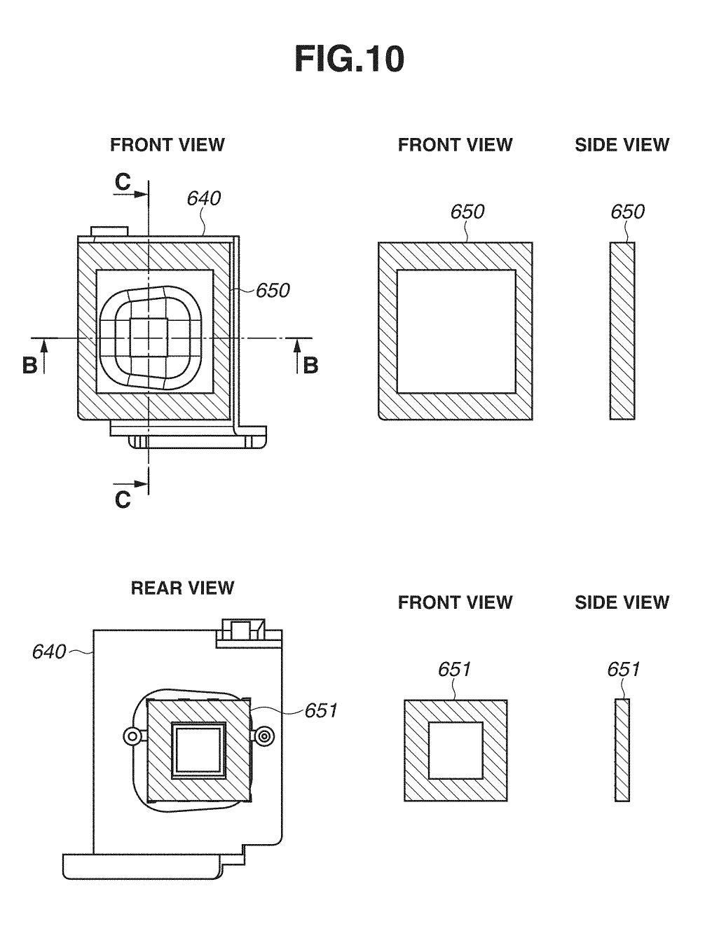

FIGS. 10A and 10B are diagrams illustrating shock-absorbing members attached to the horn 640. FIG. 10A is a diagram illustrating a shock-absorbing member attached to the horn 640 on a side of the cover member 301, and FIG. 10B is a diagram illustrating a shock-absorbing member attached to the horn 640 on a side of the board 620.

As illustrated in FIG. 10A, a shock-absorbing member 650 is arranged between the horn 640 and the cover member 301. The shock-absorbing member 650 is made of sponge. Further, the shock-absorbing member 650 has an opening larger than the opening of the horn 640 on the side of the cover member 301.

As illustrated in FIG. 10B, the shock-absorbing member 651 is arranged between the horn 640 and the board 620. Similar to the shock-absorbing member 650, the shock-absorbing member 651 is made of sponge. Further, the shock-absorbing member 651 has an opening larger than the opening of the horn 640 on the side of the board 620.

It is desirable for the shock-absorbing members 650 and 651 to be made of a material having a high sound absorption property and a high sound insulation property. As a material having the high sound absorption property, for example, porous material having a rough surface, an inner portion of which has a bubble-shaped cell structure, i.e., glass wool, rock wool, or flexible urethane form, may desirably be used for the shock-absorbing members 650 and 651. Further, as a material having the high sound insulation property, a flexible material having a small compression stress, i.e., sponge or rubber, which comfortably fits into an irregular-shaped adherend, may be used for the shock-absorbing members 650 and 651.

Further, it is desirable for the shock-absorbing members 650 and 651 to be made of a material having a high vibration absorption property and a high vibration damping property. As a material having the high vibration absorption property and the high vibration damping property, for example, an elastic damping member such as rubber or sponge may be used for the shock-absorbing members 650 and 651.

in the present exemplary embodiment, a vibration damping material such as “Eptsealer” manufactured by Nitto Denko Corporation or “CalmFlex” manufactured by Inoac Corporation is used for the shock-absorbing members 650 and 651.

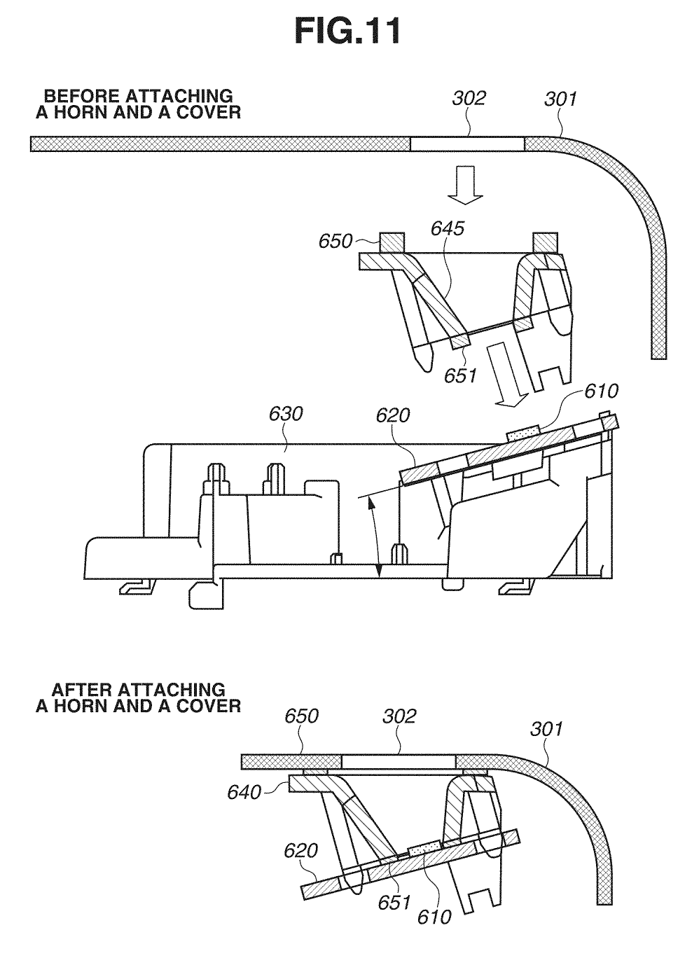

FIGS. 11A and 11B are cross-sectional diagrams of the human detection sensor unit 600. FIG. 11A is an exploded sectional view of the human detection sensor unit 600, and FIG. 11B is a cross-sectional view of the human detection sensor unit 600.

As illustrated in FIG. 11A, the shock-absorbing member 651 is not compressed when the horn 640 has not yet fixed to the pedestal 630. Further, as illustrated in FIG. 11A, the shock-absorbing member 650 is not compressed when the cover member 301 has not yet attached in front of the horn 640.

When the horn 640 is fixed to the pedestal 630, the shock-absorbing member 651 is compressed, so as to fill the space between the board 620 and the horn 640. With this configuration, the ultrasonic wave output from the ultrasonic sensor 610 can be suppressed from leaking through the space between the board 620 and the horn 640. Further, because the board 620 is brought into contact with the horn 640 via the shock-absorbing member 651, vibration of the ultrasonic sensor 610 can be suppressed from propagating to the horn 640 from the board 620.

Furthermore, when the cover member 301 is attached thereto, the shock-absorbing member 650 is compressed to fill the space between the cover member 301 and the horn 640. With this configuration, the ultrasonic wave output from the ultrasonic sensor 610 can be suppressed from leaking through the space between the cover member 301 and the horn 640. Further, because the horn 640 is brought into contact with the cover member 301 via the shock-absorbing member 650, vibration of the ultrasonic sensor 610 can be suppressed from propagating to the cover member 301 from the horn 640.

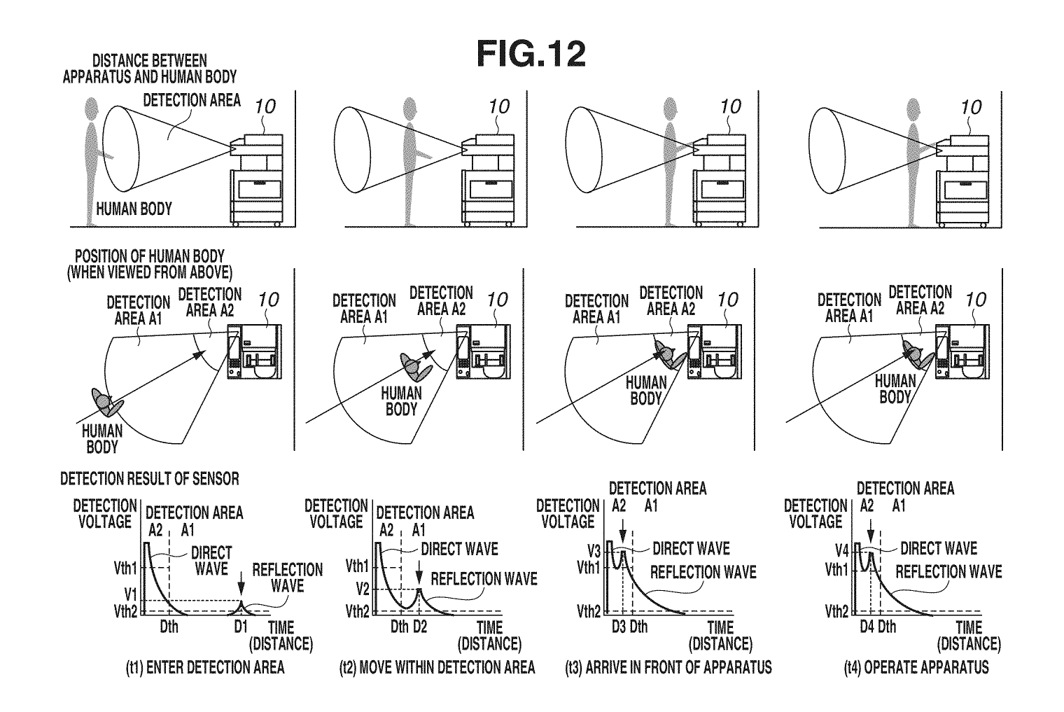

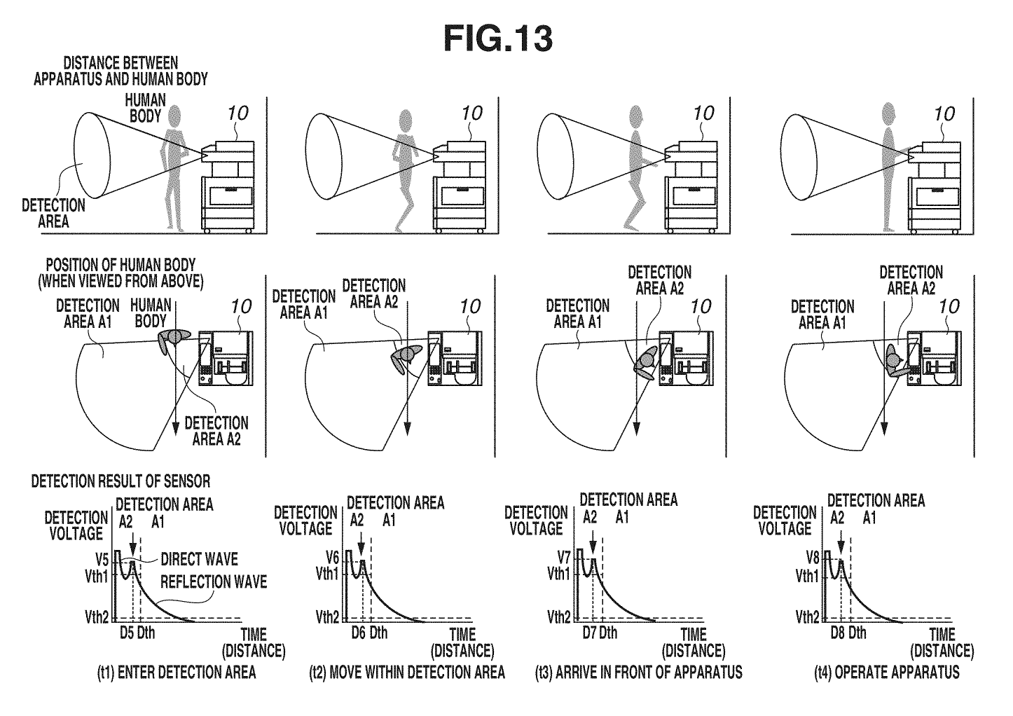

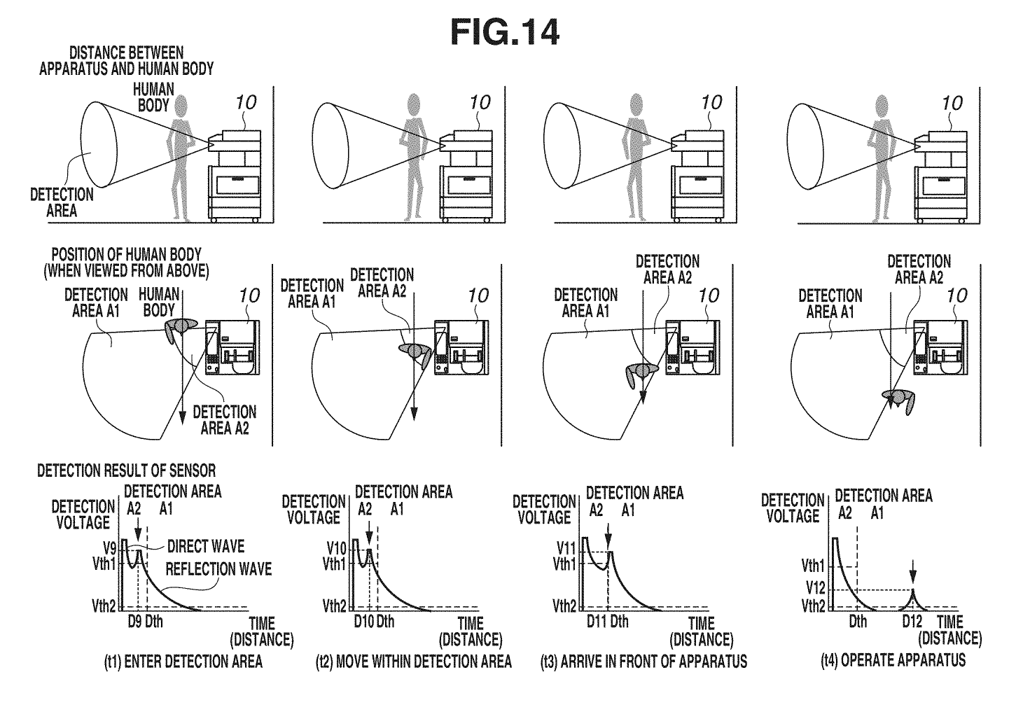

FIG. 12 is a diagram illustrating a state where the user approaches the MFP 10 from the front side thereof. In FIG. 12, a diagram in an upper row illustrates a positional relationship between the MFP 10 and the user viewed from the side, a diagram in a middle row illustrates the positional relationship between the MFP 10 and the user viewed from the above, and a diagram in a lower row illustrates a detection result of the ultrasonic sensor 610. Further, in FIG. 12, respective states (t1) to (t4) are illustrated and sequentially arranged from the left. In FIGS. 13 and 14 described below, respective states (t1) to (t4) are illustrated and arranged in a similar manner.

As illustrated in the lower row in FIG. 12, a wave form as a detection result of the ultrasonic sensor 610 includes a wave form of an oscillated ultrasonic wave and a wave form of a reflected wave. The ultrasonic sensor 610 according to the present exemplary embodiment oscillates for a predetermine period to output the ultrasonic wave. Therefore, the oscillation for outputting the ultrasonic wave has an influence on the initial stage of the detection result of the ultrasonic sensor 610. Then, the ultrasonic sensor receives a reflected wave of the ultrasonic wave reflected on the human or the object. The ultrasonic sensor 610 outputs the sound pressure intensity of the reflected wave as a voltage value (this voltage value is taken as a detection vibration amplitude V). Although the above-described wave form caused by the oscillation does not appear if the ultrasonic sensor 610 is separately configured of an output unit for outputting the ultrasonic wave and a receiving unit for receiving the reflected wave, a wave form similar to the wave form illustrated in FIG. 12 is acquired because the ultrasonic wave output from the output unit is directly received by the receiving unit.

The state (t1) in FIG. 12 illustrates a state where the user enters an area detectable by the ultrasonic sensor 610. As a detection result of the ultrasonic sensor 610, a detection vibration amplitude V1 greater than a predetermined threshold vibration amplitude Vth2 is generated when a time D1 has passed after oscillation of the ultrasonic wave. The time D1 is a time taken for the output ultrasonic wave to return after reflecting on the user, so that the time D1 corresponds to a distance between the MFP 10 and the user. Hereinafter, the time D1 .e., time taken for detecting a reflected wave after outputting a direct wave) is treated as a distance D1 as appropriate. In the present exemplary embodiment, it is determined that a person exists in a detection area A1 when a detection vibration amplitude V greater than the threshold vibration amplitude Vth2 is detected in a distance longer than a predetermined distance Dth (hereinafter, referred to as “threshold distance Dth”). Further, it is determined that a person exists in a detection area A2 when a detection vibration amplitude V greater than a threshold vibration amplitude Vth1 (Vth1>Vth2) is detected in a distance shorter than the threshold distance Dth. When a user exists in a position far from the ultrasonic sensor 610, a reflected wave returning from the faraway place is diffused, so that not all of the reflected wave can be received.

Therefore, the detection vibration amplitude is attenuated and reduced. At t1 in FIG. 12, because the detection vibration amplitude V greater than the threshold vibration amplitude Vth1 is not generated in a distance shorter than the threshold distance Dth, the MFP 10 remains in a sleep mode.

The state (t2) in FIG. 12 illustrates a state where the user moves toward the detection area A2, but has not entered the detection area A2.

As a detection result of the ultrasonic sensor 610, a detection vibration amplitude V2 greater than the threshold vibration amplitude Vth2 is output at a distance D2 that is shorter than the distance D1 and longer than the threshold distance Dth. The detection vibration amplitude V2 is greater than the detection vibration amplitude V1. In the state (t2) in FIG. 12, the detection vibration amplitude V greater than the threshold vibration amplitude Vth1 is not generated in a distance shorter than the threshold distance Dth, so that the MFP 10 remains in a sleep mode.

The state t3 in FIG. 12 illustrates a state where the user enters the detection area A2. As a detection result of the ultrasonic sensor 610, a detection vibration amplitude V3 greater than the threshold vibration amplitude Vth1 is output in a distance D3 shorter than the threshold distance Dth. In the state (t3) in FIG. 12, although the detection vibration amplitude V greater than the threshold vibration amplitude Vth1 is generated in a distance shorter than the threshold distance Dth, the MFP 10 remains in a sleep mode because the detection vibration amplitude V is not continuously generated for a predetermined period.

The state (t4) in FIG. 12 illustrates a state where the user stays within the detection area A2. As a detection result of the ultrasonic sensor 610, a detection vibration amplitude V4 greater than the threshold vibration amplitude Vth1 is output in a distance D4 shorter than the threshold distance Dth. When the detection vibration amplitude V greater than the threshold vibration amplitude Vth1 is continuously generated for a predetermined period in a distance shorter than the threshold distance Dth, the MFP 10 cancels the sleep mode and shifts to the stand-by mode. example, a predetermined period may be 300 ms.

FIG. 13 is a diagram illustrating a state where the user approaches the MFP 10 from the side.

A state (t1) in FIG. 13 illustrates a state where the user enters an area detectable by the ultrasonic sensor 610. As a detection result of the ultrasonic sensor 610, a detection vibration amplitude V5 greater than the threshold vibration amplitude Vth1 is output in a distance D5 shorter than the threshold distance Dth. At this point, the detection vibration amplitude V greater than the threshold vibration amplitude Vth1 is not continuously generated for a predetermined period (e.g., 300 ms) in a distance shorter than the threshold distance Dth, so that the MFP 10 remains in the sleep mode.

A state (t2) in FIG. 13 illustrates a state where the user moves inside the detection area A2. As a detection result of the ultrasonic sensor 610, a detection vibration amplitude V6 greater than the threshold vibration amplitude Vth1 is output in a distance D6 shorter than the threshold distance Dth. Similarly, at this point, the detection vibration amplitude V greater than the threshold vibration amplitude Vth1 is not continuously generated for a predetermined time (e.g., 300 ms) in a distance shorter than the threshold distance Dth, so that the MFP 10 remains in the sleep mode.

A state (t3) in FIG. 13 illustrates a state where the user arrives at the front of the MFP 10. As a detection result of the ultrasonic sensor 610, a detection vibration amplitude V7 greater than the threshold vibration amplitude Vth1 is output in a distance D7 shorter than the threshold distance Dth. Similarly, at this point, the detection vibration amplitude V greater than the threshold vibration amplitude Vth1 is not continuously generated for a predetermined time (e.g., 300 ms)) in a distance shorter than the threshold distance Dth, so that the MFP 10 remains in the sleep mode.

The state (t4) in FIG. 13 illustrates a state where the user stays in front of the MFP 10. As a detection result of the ultrasonic sensor 610, a detection vibration amplitude V8 greater than the threshold vibration amplitude Vth1 is output in a distance D8 shorter than the threshold distance Dth. At this point, the detection vibration amplitude V greater than the threshold vibration amplitude Vth1 is continuously generated for a predetermined time (e.g., 300 ms) in a distance shorter than the threshold distance Dth, so that the MFP 10 cancels the sleep mode and returns to the stand-by mode.

FIG. 14 is a diagram illustrating a state where a person passes in front of the MFP 10.

The state (t1) in FIG. 14 illustrates a state where the user enters an area detectable by the ultrasonic sensor 610. As a detection result of the ultrasonic sensor 610, a detection vibration amplitude V9 greater than the threshold vibration amplitude Vth1 is output in a distance D9 shorter than the threshold distance Dth. At this point, the detection vibration amplitude V greater than the threshold vibration amplitude Vth1 is not continuously generated for a predetermined time (e.g., 300 ms) in a distance shorter than the threshold distance Dth, so that the MFP 10 remains in the sleep mode.

A state (t2) in FIG. 14 illustrates a state where person moves inside the detection area A2. As a detection result of the ultrasonic sensor 610, a detection vibration amplitude 10 greater than the threshold vibration amplitude Vth1 is output in a distance D10 shorter than the threshold distance Dth. Similarly, at this point, the detection vibration amplitude V greater than the threshold vibration amplitude Vth1 is not continuously generated for a predetermined time (e.g., 300 ms) in a distance shorter than the threshold distance Dth, so that the MFP 10 remains in the sleep mode.

A state (t3) in FIG. 14 illustrates a state where the person moves outside the detection area A2. As a detection result of the ultrasonic sensor 610, a detection vibration amplitude V11 greater than the threshold vibration amplitude Vth1 is output in a distance D11 longer than the threshold distance Dth. Because the detection vibration amplitude V11 greater than the threshold vibration amplitude Vth1 is not generated in a distance shorter than the threshold distance Dth, the MFP 10 remains in a sleep mode.

A state (t4) in FIG. 14 illustrates a state where the person moves outside the detection area A1. As a detection result of the ultrasonic sensor 610, a detection vibration amplitude V12 smaller than the threshold vibration amplitude Vth1 is output in a distance D12 longer than the threshold distance Dth. Because the detection vibration amplitude V11 greater than the threshold vibration amplitude Vth1 is not generated in a distance shorter than the threshold distance Dth, the MFP 10 remains in a sleep mode. When the person starts moving away from the place (i.e., a position in front of the operation unit 500) where the user operates the MFP 10 as illustrated in the state (t4) in FIG. 14, the detection distance D gradually becomes longer, and the detection vibration amplitude V gradually becomes smaller.

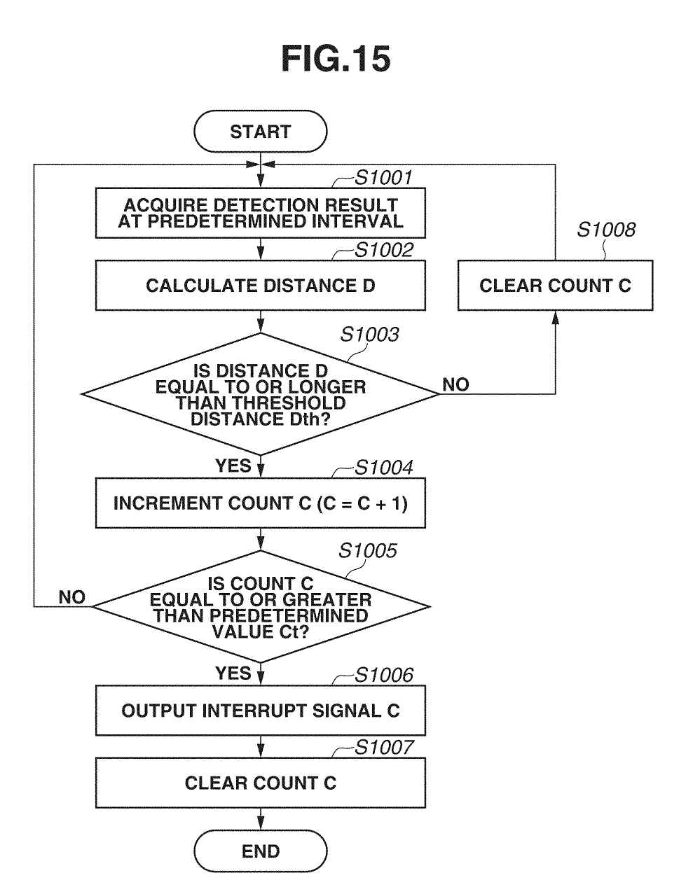

FIG. 15 is a flowchart illustrating return algorithm based on a detection result of the ultrasonic sensor 610. The microcomputer 514 of the MFP 10 executes respective steps in FIG. 15 according to a program.

In step S1001, the microcomputer 514 acquires a detection result of the ultrasonic sensor 610 at a predetermined interval (e.g., 100 ms). In step S1002, based on the detection result acquired from the ultrasonic sensor 610, the microcomputer 514 calculates a distance D at which a detection vibration amplitude V greater than a threshold vibration amplitude Vth1 is generated. Then, in step S1003, the microcomputer 514 determines whether the calculated distance D is equal to or longer than a predetermined threshold distance Dth.

If the microcomputer 514 determines that the calculated distance D is equal to or longer than the predetermined threshold distance Dth (YES in step S1003), the processing proceeds to step S1004. In step S1004, the microcomputer 514 increments a count C. Next, in step S1005, the microcomputer 514 determines whether the count C is equal to or greater than a predetermined value Ct (e.g., Ct=4). If the microcomputer 514 determines that the count C is equal to or greater than the predetermined value Ct (YES in step S1005), the processing proceeds to step S1006. In step S1006, the microcomputer 514 outputs an interrupt signal C to the power source control unit 211. The power source control unit 211 receives the interrupt signal C and makes the MFP 10 return to a stand-by mode from a sleep mode. Then, in step S1007, the microcomputer 514 clears the count C.

In addition, in step S1003, if the microcomputer 514 determines that the calculated distance C is shorter than the threshold distance Dth (NO in step S1004), the processing proceeds to step S1008. In step S1008, the microcomputer 514 clears the count C.

### Modification Example

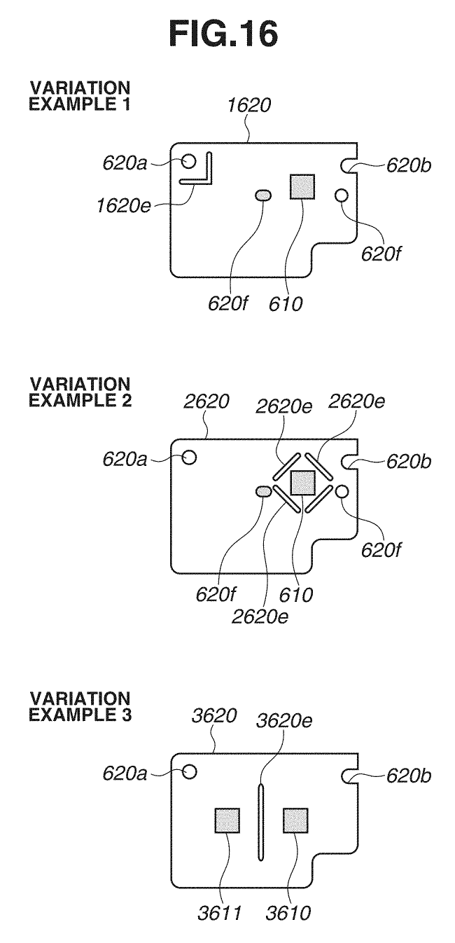

FIGS. 16A, 16B, and 16C are diagrams illustrating modification examples of a board on which an ultrasonic sensor is mounted.

In the above-described exemplary embodiment, although a configuration in which a plurality of slits is provided on the board 620 has been described as an example, the number of slits may be one. More specifically, as illustrated in FIG. 16A, on a board 1620 as a modification example 1, an L-shaped slit 1620e is formed at a position in the vicinity of a screw hole 620a.

Further, in the above-described exemplary embodiment, although a configuration in which the slits 620c and 620d are formed on both sides of the ultrasonic sensor 610 has been described as an example, slits may be provided so as to surround the ultrasonic sensor 610. More specifically, as illustrated in FIG. 16B, on a board 2620 as a modification example 2, four slits 2620e are formed so as to surround the ultrasonic sensor 610.

Furthermore, in the above-described exemplary embodiment, although a single ultrasonic sensor 610 outputs and receives the ultrasonic wave, the ultrasonic wave may be output and received by different devices. In this case, as illustrated in FIG. 160, a device (ultrasonic wave transmission unit) 3610 for outputting the ultrasonic wave and a device (ultrasonic wave receiving unit) 3611 receiving the ultrasonic wave are mounted on a board 3620. Then, a slit 3620e is formed on a board 3620, at a position between the devices 3610 and 3611.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one more of the above-described embodiment(s and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact. disc (CD), digital versatile disc (DVD), or Blu-ray Disc (BD)™), a flash memory device, a memory card, and the like.

While aspects of the present invention have been described with reference to exemplary embodiments, it is to be understood that aspects of the invention are not limited to the disclosed exemplary embodiments. The scope of the following claims is to be accorded the broadest interpretation so as to encompass all such modifications and equivalent structures and functions.

This application claims the benefit of Japanese Patent Application No. 2016-150105, filed Jul. 29, 2016, which is hereby incorporated by reference herein in its entirety.

What is claimed is:

1. A printed circuit board, on which a vibration component for generating vibration is mounted, is fixed to a pedestal, the printed circuit board comprising:
first slit formed on a straight line that connects a first position where the vibration component is mounted on the printed circuit board and a second position where the printed circuit board is in contact with the pedestal.

2. The printed circuit board according to claim 1, wherein a length of the first slit in a lengthwise direction is longer than a length of the vibration component in the lengthwise direction.

3. The printed circuit board according to claim 1, wherein a lengthwise direction of the first slit is a direction orthogonal to a lengthwise direction of the printed circuit board.

4. The printed circuit board according to claim 1, further comprising a second slit formed on a line that connects the first position where the vibration component is mounted on the printed circuit board and the second position where the printed circuit board is in contact with the pedestal.

5. The printed circuit board according to claim 4, wherein a length of the second slit in a lengthwise direction is longer than a length of the vibration component in the lengthwise direction.

6. The printed circuit board according to claim 4, wherein a lengthwise direction of the second slit is a direction orthogonal to a lengthwise direction of the printed circuit board.

7. The printed circuit board according to claim 4, wherein the first slit and the second slit are respectively formed on first and second sides of the vibration component.

8. The printed circuit board according to claim 1, further comprising a third slit formed on a straight line that connects the first position where the vibration component is mounted on the printed circuit board and the second position where the printed circuit board is in contact with the pedestal.

9. The printed circuit board according to claim 8, wherein the first slit and the third slit are respectively formed on one side and another side of a center of the straight line that connects the first position where the vibration component is mounted on the printed circuit board and the second position where the printed circuit board in contact with the pedestal.

10. The printed circuit board according to claim 1, wherein the first slit is formed into an L-shape.

11. The printed circuit board according to claim 1, further comprising a through-hole through which a screw for fixing the printed circuit board to the pedestal passes on the second position where the printed circuit board is in contact with the pedestal, and
wherein the first slit is formed so as to surround the through-hole.

12. The printed circuit board according to claim 1, wherein the vibration component is configured to vibrate to output a sonic wave and to receive a reflected wave of the output sonic wave.

13. The printed circuit board according to claim 1, wherein the vibration component vibrates when an information processing apparatus provided with the printed circuit board is in a sleep mode.

14. An information processing apparatus having a sleep mode and a stand-by mode, comprising:
a pedestal;
a printed circuit board, on which a vibration component configured to generate vibration, is mounted fixed to the pedestal, wherein a first slit is formed on a straight line that connects first position where the vibration component is mounted on the printed circuit board and a second position where the printed circuit board is in contact with the pedestal; and
a control unit configured to change a power mode of the information processing apparatus based on a detection result of a reflected wave of a sonic wave output through vibration of the vibration component mounted on the printed circuit board.
